(19) United States
(12) Patent Application Publication
(10) Pub. No.: US 2025/0366216 A1
(43) Pub. Date: Nov. 27, 2025

(54) ESD CLAMP CIRCUIT WITH LATCH

(71) Applicant: Taiwan Semiconductor Manufacturing Company, Ltd., Hsinchu (TW)

(72) Inventors: Tao-Yi HUNG, Hsinchu (TW); Wun-Jie LIN, Hsinchu City (TW); Kuo-Ji CHEN, Hsinchu (TW)

(21) Appl. No.: 18/671,605

(22) Filed: May 22, 2024

(51) Int. Cl. H01L 27/02

(52) U.S. Cl. CPC H10D 89/819

(57) ABSTRACT

A device including a discharge device, an electro-static discharge (ESD) detection circuit, and a latch circuit. The discharge device is connected to a first net and a second net and configured to discharge ESD current during an ESD event. The ESD detection circuit is connected to the discharge device and configured to detect the ESD event and activate the discharge device to discharge the ESD current during the ESD event. The latch circuit including an input and an output, the input configured to receive a pre-charge voltage to latch the latch circuit during a pre-charge stage and track a first net voltage on the first net at the output during a ramp-up stage. The output coupled to the discharge device to prevent activation of the discharge device during the pre-charge stage and the ramp-up stage.

### BACKGROUND

Electro-static discharge (ESD) is the release of static electricity in a sudden and momentary flow of electric current between two differently charged objects. Some ESD events create visible sparks associated with the current flow between the objects, while other less dramatic forms of ESD may be neither seen nor heard, yet still cause damage to electronic devices. To prevent damage to circuits from ESD, the electronic devices often include ESD protection circuits to discharge the ESD.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating an ESD protection device, in accordance with some embodiments.

FIG. 2 is a diagram schematically illustrating another ESD protection device, in accordance with some embodiments.

FIG. 3 is a diagram schematically illustrating operation of the ESD protection device of FIG. 2 during the pre-charge stage, in accordance with some embodiments.

FIG. 4 is a diagram schematically illustrating operation of the ESD protection device of FIG. 2 during the ramp-up stage, in accordance with some embodiments.

FIG. 5 is a timing diagram illustrating the shut-down voltage VSD, the output signal OUT, and the power voltage VDD during the VSD pre-charge stage and the VDD ramp-up stage of the ESD protection device of FIG. 2, in accordance with some embodiments.

FIG. 6 is a diagram schematically illustrating operation of the ESD protection device of FIG. 2 during an ESD event, in accordance with some embodiments.

FIG. 7 is a diagram schematically illustrating an ESD protection device that includes a PMOS discharge device and a different ESD detection circuit, in accordance with some embodiments.

FIG. 8 is a diagram schematically illustrating an ESD protection device for an overdrive circuit that includes two power voltages VDD1 and VDD2 and a reference voltage VSS, in accordance with some embodiments.

FIG. 9 is a flow-chart diagram illustrating a method of operation of an ESD protection device during pre-charge and ramp-up stages and during an ESD event, in accordance with some embodiments.

FIG. 10 is a diagram schematically illustrating a method of operating an ESD protection device, also referred to as an ESD clamp device, in accordance with some embodiments.

FIG. 11 is a block diagram schematically illustrating an example of a computer system configured to provide the electronic devices, semiconductor devices, and methods of the current disclosure, in accordance with some embodiments.

FIG. 12 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

ESD protection circuits discharge ESD during ESD events to protect other circuits in the electronic devices. Sometimes, a clamp circuit is used in an ESD protection circuit. The clamp circuit may be referred to as an ESD clamp circuit, an ESD power-rail clamp circuit, and/or a pclamp circuit. The clamp circuit prevents circuit failures by bypassing the positive or negative ESD current through a low resistance path during ESD events. At least some clamp circuits include an ESD detection circuit and a discharge device for discharging the ESD. The clamp circuit shows high impedance during standby mode and low impedance during ESD events. In some embodiments, the discharge device is a big field-effect transistor (bigFET). In some embodiments, the discharge device is an N-channel metal-oxide-semiconductor (NMOS) bigFET.

Disclosed embodiments provide a device including a discharge device, an ESD detection circuit, and a latch circuit. The discharge device is connected to a first net, such as a power voltage net VDD, and a second net, such as a reference voltage net VSS, and configured to discharge ESD current during an ESD event. The ESD detection circuit is connected to the discharge device and configured to detect the ESD event and activate the discharge device to discharge ESD current during the ESD event. The latch circuit includes an input configured to receive a pre-charge voltage, such as a shut-down voltage VSD, to latch the latch circuit during a pre-charge stage and track the voltage on the first net at an output of the latch circuit during a ramp-up stage. The output is coupled to the discharge device to prevent activation of the discharge device during the pre-charge stage and the ramp-up stage, which provides a low in-rush current during the pre-charge stage and the ramp-up stage.

A method of operating an ESD clamp device includes receiving a pre-charge voltage at an input of a latch circuit during a pre-charge stage to latch the latch circuit, tracking a first net voltage, such as a power voltage VDD, at an output of the latch circuit during a ramp-up stage, and preventing activation of a discharge device during the pre-charge stage and the ramp-up stage.

Advantages of the clamp device and method of operating the clamp device include preventing activation of the discharge device during the pre-charge stage to achieve low in-rush current, tracking the output of the latch circuit to the power voltage VDD during the ramp-up stage to prevent activation of the discharge device and achieve low in-rush current through the discharge device during the ramp-up stage, and disabling the latch circuit and activating the discharge device, by an ESD detection circuit, to discharge ESD currents through the discharge device during an ESD event.

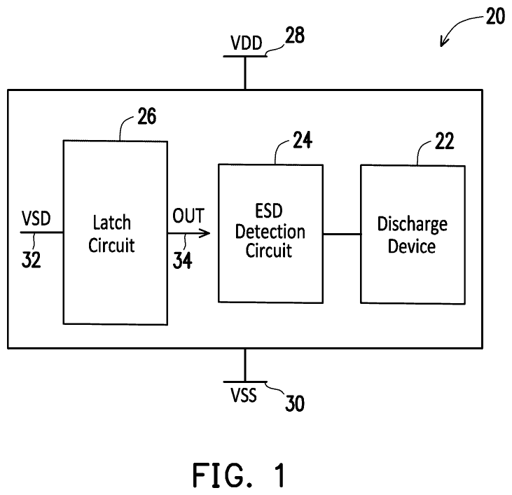

FIG. 1 is a diagram schematically illustrating an ESD protection device 20, in accordance with some embodiments. The device 20 includes a discharge device 22, an ESD detection circuit 24, and a latch circuit 26. The device 20 can be a semiconductor device, an integrated circuit device, an electronic device, an ESD power-rail clamp device, an ESD clamp device, and/or another device. In some embodiments, at least one of the discharge device 22, the ESD detection circuit 24, and the latch circuit 26 is connected to a first net 28, such as the power voltage net VDD. In some embodiments, at least one of the discharge device 22, the ESD detection circuit 24, and the latch circuit 26 is connected to a second net 30, such as the reference voltage net VSS. In some embodiments, each of the discharge device 22, the ESD detection circuit 24, and the latch circuit 26 is connected to the first net 28, such as the power voltage net VDD. In some embodiments, each of the discharge device 22, the ESD detection circuit 24, and the latch circuit 26 is connected to the second net 30, such as the reference voltage net VSS. In some embodiments, the reference voltage net 30 is ground.

The discharge device 22 is configured to discharge ESD current during an ESD event. The discharge device 22 is connected to the ESD detection circuit 24 and to the first net 28, such as the power voltage net VDD, and the second net 30, such as the reference voltage net VSS. In some embodiments, the discharge device 22 includes a bigFET. In some embodiments, the discharge device 22 includes an NMOS bigFET.

The ESD detection circuit 24 is connected to the discharge device 22 and configured to detect the ESD event and activate the discharge device 22 to discharge ESD current during the ESD event. In some embodiments, the ESD detection circuit 24 includes a resistor-capacitor (RC) network and an inverter having an inverter input and an inverter output. The RC network is connected to the inverter input and the discharge device 22 is connected to the inverter output.

The latch circuit 26 includes an input 32 configured to receive a pre-charge voltage, such as the shut-down voltage VSD, to latch the latch circuit 26 during a pre-charge stage and to track the voltage on the first net 28 at an output 34 of the latch circuit 26 during a ramp-up stage. The output 34 provides an output signal OUT and is coupled to the discharge device 22 to prevent activation of the discharge device 22 during the pre-charge stage and the ramp-up stage. This provides a low in-rush current during the pre-charge stage and the ramp-up stage. In some embodiments, the output 34 of the latch circuit 26 is connected to the ESD protection circuit 24. In some embodiments, the output 34 of the latch circuit 26 is connected directly to the discharge device 22.

In operation, during the pre-charge stage, the latch circuit 26 receives the pre-charge shut-down voltage VSD at the input 32 of the latch circuit 26 to latch the output 34 of the latch circuit 26 at a high voltage. The high voltage at the output 34 biases off the discharge device 22 and provides a low in-rush current during the pre-charge stage. During the ramp-up stage, the output 34 of the latch circuit 26 tracks the voltage on the first net 28, which prevents activation of the discharge device 22 and provides a low in-rush current during the ramp-up stage. During an ESD event, the ESD detection circuit 24 detects the ESD event and disables the latch circuit 26. Also, during the ESD event, the ESD detection circuit 26 biases on the discharge device 22 to discharge the ESD current.

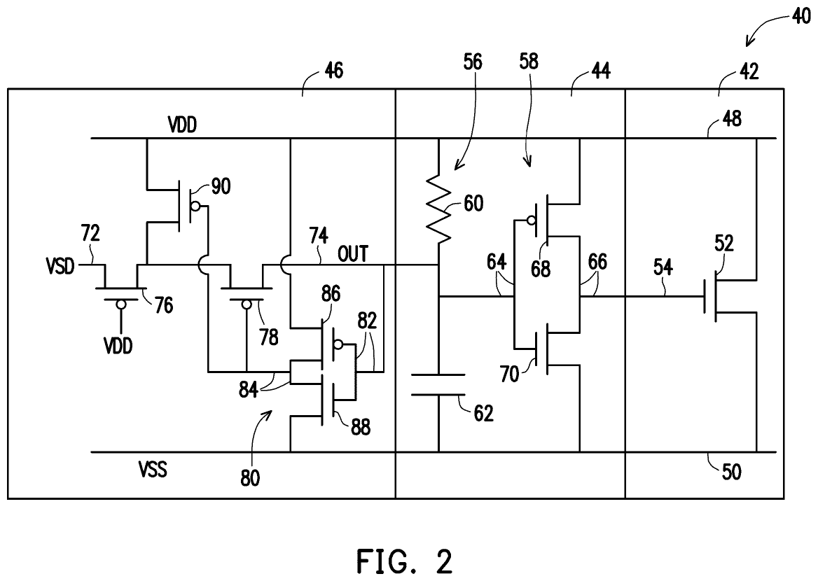

FIG. 2 is a diagram schematically illustrating another ESD protection device 40, in accordance with some embodiments. The device 40 can be a semiconductor device, an integrated circuit device, an electronic device, an ESD power-rail clamp device, an ESD clamp device, and/or another device. The device 40 includes a discharge device 42, an ESD detection circuit 44, and a latch circuit 46. In some embodiments, the device 40 is like the device 20 of FIG. 1. In some embodiments, the discharge device 42 is like the discharge device 22 of FIG. 1. In some embodiments, the ESD detection circuit 44 is like the ESD detection circuit 24 of FIG. 1. In some embodiments, the latch circuit 46 is like the latch circuit 26 of FIG. 1.

The discharge device 42 is configured to discharge the ESD current during an ESD event. The discharge device 42 is connected to a first net 48 that provides a power voltage VDD and to a second net 50 that provides a reference voltage VSS, such as ground. The discharge device 42 includes an NMOS bigFET 52 that has a gate 54 connected to the ESD detection circuit 44, and a drain/source path with one side of the drain/source path connected to the first net 48 and another side of the drain/source path connected to the second net 50. Drain/source path may refer to a current path through a transistor from the source to the drain or from the drain to the source, individually or collectively dependent upon the context. Also, drain/source terminal(s) may refer to a source or a drain, individually or collectively dependent upon the context.

The ESD detection circuit 44 is connected to the discharge device 42 and configured to detect the ESD event and activate the discharge device 42 to discharge the ESD current during the ESD event. The ESD detection circuit 44 includes an RC network 56 and an inverter 58. The RC network 56 includes a resistor 60 and a capacitor 62. The inverter 58 includes an input 64 and an output 66. One end of the resistor 60 is connected to the first net 48 and another end of the resistor 60 is connected to one end of the capacitor 62 and to the input 64 of the inverter 58. Another end of the capacitor 62 is connected to the second net 50.

The inverter 58 includes a first inverter PMOS transistor 68 and a first inverter NMOS transistor 70. One end of a drain/source path of the first inverter PMOS transistor 68 is connected to the first net 48 and another end of the drain/source path of the first inverter PMOS transistor 68 is connected to one end of a drain/source path of the first inverter NMOS transistor 70 and the output 66 of the inverter 58. Another end of the drain/source path of the first inverter NMOS transistor 70 is connected to the second net 50. A gate of the first inverter PMOS transistor 68 is connected to a gate of the first inverter NMOS transistor 70 at the input 64 of the inverter 58. The output 66 of the inverter 58 is connected to the gate 54 of the NMOS bigFET 52.

The latch circuit 46 includes a latch input 72 configured to receive a pre-charge shut-down voltage VSD to latch the latch circuit 46 during a pre-charge stage. Also, the latch circuit 46 tracks the voltage on the first net 48 at a latch output 74 of the latch circuit 46 during a ramp-up stage. The latch output 74 provides an output signal OUT to the RC network 56 and the input 64 of the inverter 58 to prevent activation of the NMOS bigFET 52 during the pre-charge stage and the ramp-up stage. This provides a low in-rush current during the pre-charge stage and the ramp-up stage.

The latch circuit 46 includes a first PMOS transistor 76 having one end of a first drain/source path connected to the latch input 72 and another end of the first drain/source path connected to one end of a second drain/source path of a second PMOS transistor 78. Another end of the second drain/source path of the second PMOS transistor 78 is connected to the latch output 74. A first gate of the first PMOS transistor 76 is connected to the first net 48.

The latch circuit 46 includes a latch inverter 80 that has a latch inverter input 82 and a latch inverter output 84. The latch output 74 of the latch circuit 46 is connected to the latch inverter input 82, and a gate of the second PMOS transistor 78 is connected to the latch inverter output 84. The latch inverter 80 includes a third PMOS transistor 86 and a first NMOS transistor 88. One end of a third drain/source path of the third PMOS transistor 86 is connected to the first net 48 and another end of the third drain/source path of the third PMOS transistor 86 is connected to one end of a fourth drain/source path of the first NMOS transistor 88 and the latch inverter output 84. Another end of the fourth drain/source path of the first NMOS transistor 88 is connected to the second net 50. A gate of the third PMOS transistor 86 is connected to a gate of the first NMOS transistor 88 and the latch inverter input 82. A fourth PMOS transistor 90 has one end of a fourth drain/source path connected to the first drain/source path and the second drain/source path and another end connected to the first net 48. A gate of the fourth PMOS transistor 90 is connected to the latch inverter output 84.

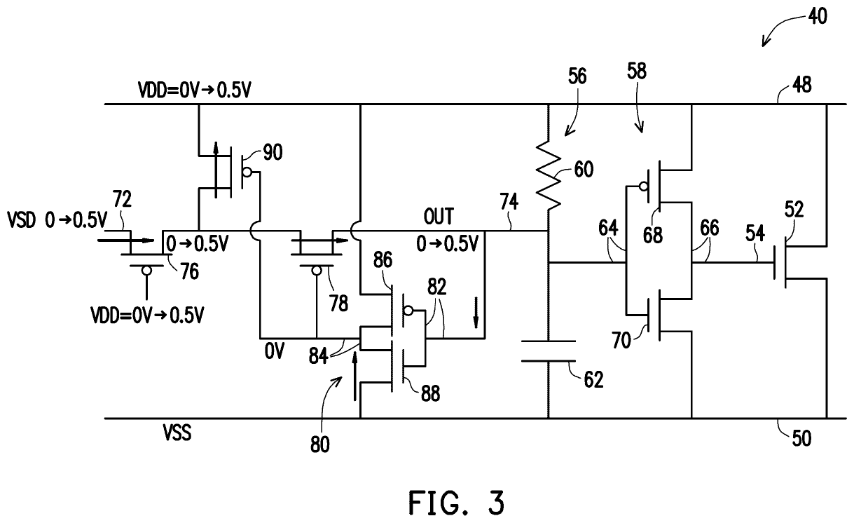

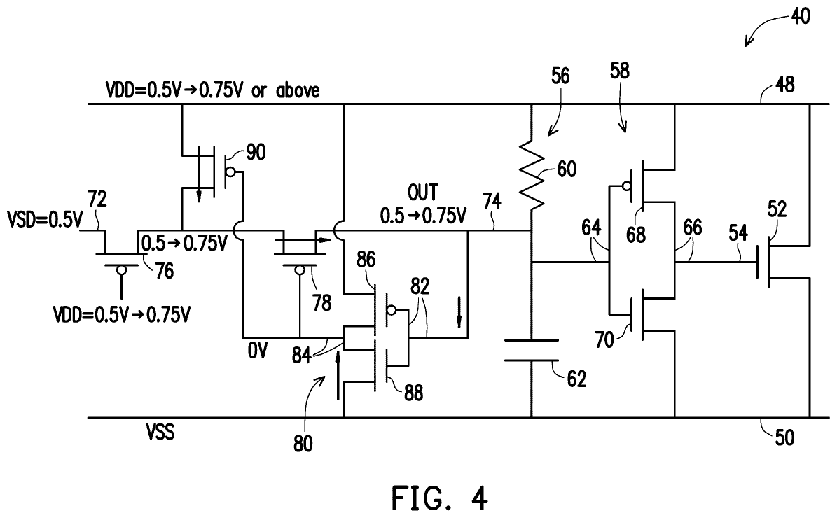

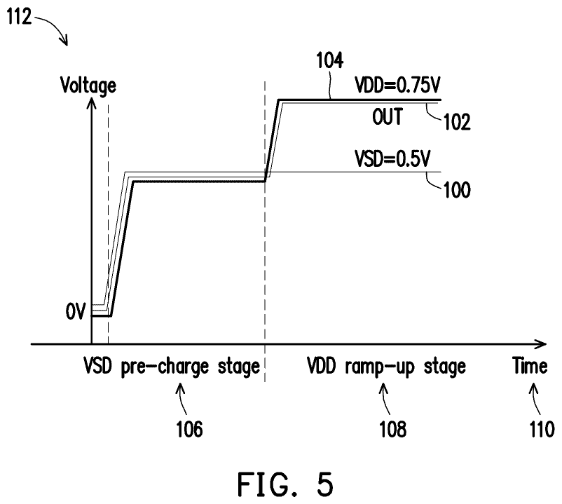

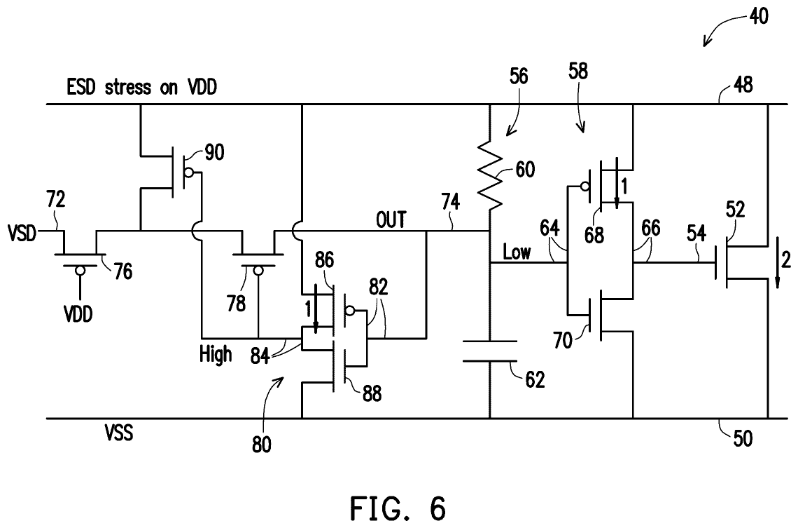

FIGS. 3-6 are diagrams schematically illustrating the operation of the ESD protection device 40 of FIG. 2, in accordance with some embodiments. FIGS. 3 and 4 are diagrams schematically illustrating the operation of the ESD protection device 40 during the pre-charge stage and the ramp-up stage, respectively, in accordance with some embodiments. FIG. 5 is a diagram schematically illustrating a voltage and timing diagram for the pre-charge stage and the ramp-up stage, in accordance with some embodiments. FIG. 6 is a diagram schematically illustrating the operation of the ESD protection device 40 during an ESD event, in accordance with some embodiments.

FIG. 3 is a diagram schematically illustrating operation of the ESD protection device 40 during the pre-charge stage, in accordance with some embodiments. Initially, the first net 48 has a power voltage VDD of 0 volts (V) and the gate of the first PMOS transistor 76 is at 0 V. Also, the latch inverter output 84 is at 0 V, the gate of the second PMOS transistor 78 is at 0 V, and the gate of the fourth PMOS transistor 90 is at 0 V.

Next, the shut-down voltage VSD is ramped from 0 V to 0.5 V. Each of the first PMOS transistor 76, the second PMOS transistor 78, and the fourth PMOS transistor 90 is biased on, such that the output signal OUT provided by the latch output 74 ramps from 0 V to 0.5 V and the power voltage VDD on the first net 48 ramps from 0 V to 0.5 V.

With the output signal OUT at 0.5 V, the third PMOS transistor 86 is biased off and the first NMOS transistor 88 is biased on to hold the latch inverter output 84 at 0 V. Also, the power voltage VDD on the first net 48 ramps from 0 V to 0.5 V to bias off the first PMOS transistor 76, and the output signal OUT is latched at 0.5 V.

With the output signal OUT at 0.5 V, the first inverter PMOS transistor 68 is biased off and the first inverter NMOS transistor 70 is biased on to provide 0 V at the gate 54 of the NMOS bigFET 52 and bias off the NMOS bigFET 52. This prevents activation of the NMOS bigFET 52 during the pre-charge stage and achieves a low in-rush current.

FIG. 4 is a diagram schematically illustrating operation of the ESD protection device 40 during the ramp-up stage, in accordance with some embodiments. Initially, the first net 48 has a power voltage VDD of 0.5 V and the gate of the first PMOS transistor 76 is at 0.5 V. Also, the latch inverter output 84 is at 0 V, the gate of the second PMOS transistor 78 is at 0 V, and the gate of the fourth PMOS transistor 90 is at 0 V. In addition, the shut-down voltage VSD is at 0.5 V and the first PMOS transistor 76 is biased off.

Next, the power voltage VDD on the first net 48 ramps from 0.5 V to 0.75 V (or above). Each of the second PMOS transistor 78 and the fourth PMOS transistor 90 is biased on, such that the output signal OUT provided by the latch output 74 ramps from 0.5 V to 0.75 V. With the output signal OUT at 0.75 V, the third PMOS transistor 86 is biased off and the first NMOS transistor 88 is biased on to hold the latch inverter output 84 at 0 V, and the latched output signal OUT ramps up to 0.75 V.

With the output signal OUT at 0.75 V, the first inverter PMOS transistor 68 is biased off and the first inverter NMOS transistor 70 is biased on to provide 0 V at the gate 54 of the NMOS bigFET 52 and bias off the NMOS bigFET 52. This prevents activation of the NMOS bigFET 52 during the ramp-up stage and achieves a low in-rush current.

FIG. 5 is a timing diagram illustrating the shut-down voltage VSD 100, the output signal OUT 102, and the power voltage VDD 104 during the VSD pre-charge stage 106 and the VDD ramp-up stage 108 of the ESD protection device 40, in accordance with some embodiments. Time is graphed along the x-axis 110 and voltage is graphed along the y-axis 112.

During the VSD pre-charge stage 106, the shut-down voltage VSD 100 is ramped from 0 V to 0.5 V, which ramps the output signal OUT 102 and the power voltage VDD 104 from 0 V to 0.5 V. This prevents activation of the NMOS bigFET 52 during the VSD pre-charge stage 106 and achieves a low in-rush current.

During the VDD ramp-up stage 108, the power voltage VDD 104 is ramped from 0.5 to 0.75 V, which ramps the output signal OUT 102 from 0.5 V to 0.75 V. This prevents activation of the NMOS bigFET 52 during the VDD ramp-up stage 108 and achieves a low in-rush current.

FIG. 6 is a diagram schematically illustrating operation of the ESD protection device 40 during an ESD event, in accordance with some embodiments. Initially, the first net 48 has a power voltage VDD of 0.75 V, the output signal OUT is at 0.75 V, and the gate of the first PMOS transistor 76 is at 0.75 V. With the output signal OUT at 0.75 V, the third PMOS transistor 86 is biased off and the first NMOS transistor 88 is biased on to hold the latch inverter output 84 at 0 V, with the gate of the second PMOS transistor 78 at 0 V and the gate of the fourth PMOS transistor 90 at 0 V. The shut-down voltage VSD is lower than the power voltage VDD at 0.75 V, such that the first PMOS transistor 76 is biased off. In addition, with the output signal OUT at 0.75 V, the first inverter PMOS transistor 68 is biased off and the first inverter NMOS transistor 70 is biased on to provide 0 V at the gate 54 of the NMOS bigFET 52 and bias off the NMOS bigFET 52.

During the ESD event, the high voltage of the ESD event is on the first net 48 and, in comparison, the output signal OUT is at a low voltage. The third PMOS transistor 86 is biased on and the first NMOS transistor 88 is biased off to provide a high voltage at the latch inverter output 84, the gate of the second PMOS transistor 78, and the gate of the fourth PMOS transistor 90. This biases off each of the second PMOS transistor 78 and the fourth PMOS transistor 90. Also, the first inverter PMOS transistor 68 is biased on and the first inverter NMOS transistor 70 is biased off to provide a high voltage at the gate 54 of the NMOS bigFET 52, which biases on the NMOS bigFET 52 to discharge the ESD current from the ESD event through the bigFET 52.

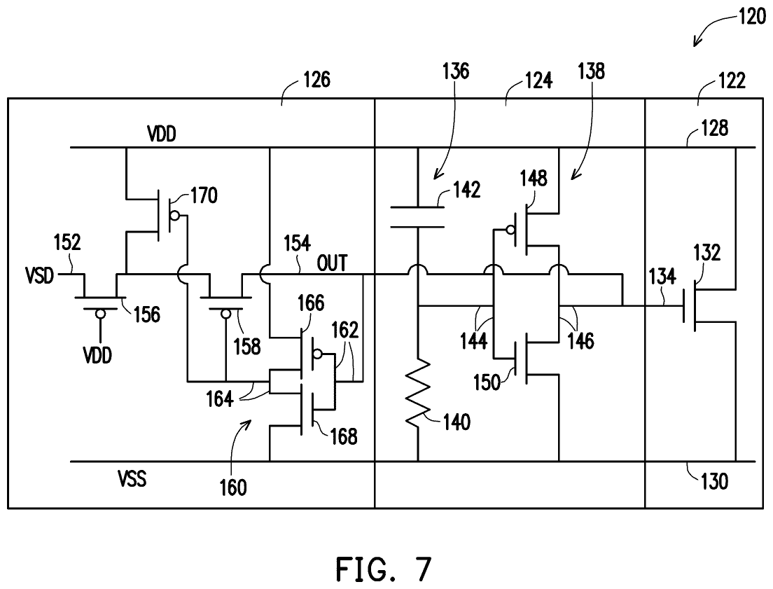

FIG. 7 is a diagram schematically illustrating an ESD protection device 120 that includes a PMOS discharge device 122 and a different ESD detection circuit 124, in accordance with some embodiments. The device 120 can be a semiconductor device, an integrated circuit device, an electronic device, an ESD power-rail clamp device, an ESD clamp device, and/or another device. The device 120 includes the discharge device 122, the ESD detection circuit 124, and a latch circuit 126 that is like the latch circuit 46 of FIG. 1. In some embodiments, the device 120 is like the device 20 of FIG. 1. In some embodiments, the discharge device 122 is like the discharge device 22 of FIG. 1. In some embodiments, the ESD detection circuit 124 is like the ESD detection circuit 24 of FIG. 1. In some embodiments, the latch circuit 126 is like the latch circuit 26 of FIG. 1.

The discharge device 122 is configured to discharge the ESD current during an ESD event. The discharge device 122 is connected to a first net 128 that provides a power voltage VDD and to a second net 130 that provides a reference voltage VSS, such as ground. The discharge device 122 includes a PMOS bigFET 132 that has a gate 134 connected to the ESD detection circuit 124 and a drain/source path with one side of the drain/source path connected to the first net 128 and another side of the drain/source path connected to the second net 130.

The ESD detection circuit 124 is connected to the discharge device 122 and configured to detect the ESD event and activate the discharge device 122 to discharge the ESD current during the ESD event. The ESD detection circuit 124 includes an RC network 136 and an inverter 138. The RC network 136 includes a resistor 140 and a capacitor 142. The inverter 138 includes an input 144 and an output 146. One end of the resistor 140 is connected to the second net 130 and another end of the resistor 140 is connected to one end of the capacitor 142 and to the input 144 of the inverter 138. Another end of the capacitor 142 is connected to the first net 128.

The inverter 138 includes a first inverter PMOS transistor 148 and a first inverter NMOS transistor 150. One end of a drain/source path of the first inverter PMOS transistor 148 is connected to the first net 128 and another end of the drain/source path of the first inverter PMOS transistor 148 is connected to one end of a drain/source path of the first inverter NMOS transistor 150 and the output 146 of the inverter 138. Another end of the drain/source path of the first inverter NMOS transistor 150 is connected to the second net 130. A gate of the first inverter PMOS transistor 148 is connected to a gate of the first inverter NMOS transistor 150 at the input 144 of the inverter 138. The output 146 of the inverter 138 is connected to the gate 134 of the PMOS bigFET 132 and to the latch output 154 of the latch circuit 126.

The latch circuit 126 includes a latch input 152 configured to receive a pre-charge shut-down voltage VSD to latch the latch circuit 126 during a pre-charge stage. Also, the latch circuit 126 tracks the voltage on the first net 128 at the latch output 154 during a ramp-up stage. The latch circuit 126 operates like the latch circuit 46 of FIGS. 2-6.

The latch output 154 provides an output signal OUT to the gate 134 of the PMOS bigFET 132 to prevent activation of the PMOS bigFET 132 during the pre-charge stage and the ramp-up stage. This provides a low in-rush current during the pre-charge stage and the ramp-up stage.

The latch circuit 126 includes a first PMOS transistor 156 having one end of a first drain/source path connected to the latch input 152 and another end of the first drain/source path connected to one end of a second drain/source path of a second PMOS transistor 158. Another end of the second drain/source path of the second PMOS transistor 158 is connected to the latch output 154. A first gate of the first PMOS transistor 156 is connected to the first net 128.

The latch circuit 126 includes a latch inverter 160 that has a latch inverter input 162 and a latch inverter output 164. The latch output 154 is connected to the latch inverter input 162, and a gate of the second PMOS transistor 158 is connected to the latch inverter output 164. The latch inverter 160 includes a third PMOS transistor 166 and a first NMOS transistor 168. One end of a third drain/source path of the third PMOS transistor 166 is connected to the first net 128 and another end of the third drain/source path of the third PMOS transistor 166 is connected to one end of a fourth drain/source path of the first NMOS transistor 168 and the latch inverter output 164. Another end of the fourth drain/source path of the first NMOS transistor 168 is connected to the second net 130. A gate of the third PMOS transistor 166 is connected to a gate of the first NMOS transistor 168 and the latch inverter input 162. A fourth PMOS transistor 170 has one end of a fourth drain/source path connected to the first drain/source path and the second drain/source path and another end connected to the first net 128. A gate of the fourth PMOS transistor 170 is connected to the latch inverter output 164.

In operation of the ESD protection device 120, during the pre-charge stage, initially the first net 128 has a power voltage VDD of 0 V and the gate of the first PMOS transistor 156 is at 0 V. Also, the latch inverter output 164 is at 0 V, the gate of the second PMOS transistor 158 is at 0 V, and the gate of the fourth PMOS transistor 170 is at 0 V.

Next, the pre-charge shut-down voltage VSD is ramped from 0 V to 0.5 V. Each of the first PMOS transistor 156, the second PMOS transistor 158, and the fourth PMOS transistor 170 is biased on, such that the output signal OUT provided by the latch output 154 ramps from 0 V to 0.5 V and the power voltage VDD on the first net 128 ramps from 0 V to 0.5 V.

With the output signal OUT at 0.5 V, the third PMOS transistor 166 is biased off and the first NMOS transistor 168 is biased on to hold the latch inverter output 164 at 0 V. Also, the power voltage VDD on the first net 128 ramps from 0 V to 0.5 V to bias off the first PMOS transistor 156. In addition, with the output signal OUT at 0.5 V, the PMOS bigFET 132 is biased off, which prevents activation of the PMOS bigFET 132 during the pre-charge stage and achieves a low in-rush current.

During the ramp-up stage, initially the first net 128 has a power voltage VDD of 0.5 V and the gate of the first PMOS transistor 156 is at 0.5 V. Also, the latch inverter output 164 is at 0 V, the gate of the second PMOS transistor 158 is at 0 V, and the gate of the fourth PMOS transistor 170 is at 0 V. In addition, the pre-charge shut-down voltage VSD is at 0.5 V and the first PMOS transistor 156 is biased off.

Next, the power voltage VDD on the first net 128 ramps from 0.5 V to 0.75 V (or above). Each of the second PMOS transistor 158 and the fourth PMOS transistor 170 is biased on, such that the output signal OUT provided by the latch output 154 ramps from 0.5 V to 0.75 V. With the output signal OUT at 0.75 V, the third PMOS transistor 166 is biased off and the first NMOS transistor 168 is biased on to hold the latch inverter output 164 at 0 V and the latched output signal OUT ramps up to 0.75 V. With the output signal OUT at 0.75 V, the PMOS bigFET 132 is biased off, which prevents activation of the PMOS bigFET 132 during the ramp-up stage and achieves a low in-rush current.

During an ESD event, initially the first net 128 has a power voltage VDD of 0.75 V, the output signal OUT is at 0.75 V, and the gate of the first PMOS transistor 156 is at 0.75 V. With the output signal OUT at 0.75 V, the third PMOS transistor 166 is biased off and the first NMOS transistor 168 is biased on to hold the latch inverter output 164 at 0 V, with the gate of the second PMOS transistor 158 at 0 V and the gate of the fourth PMOS transistor 170 at 0 V. The shut-down voltage VSD is lower than the power voltage VDD at 0.75 V, such that the first PMOS transistor 156 is biased off. In addition, with the output signal OUT at 0.75 V, the PMOS bigFET 132 is biased off.

During the ESD event, the high voltage of the ESD event is on the input 144 of the inverter 138, such that the first inverter PMOS transistor 148 is biased off and the first inverter NMOS transistor 150 is biased on to provide a low voltage at the output 146 of the inverter 138 and at the gate 134 of the PMOS bigFET 132, which biases on the PMOS bigFET 132 to discharge the ESD current from the ESD event through the PMOS bigFET 132. Also, the low voltage at the output 146 biases on the third PMOS transistor 166 and biases off the first NMOS transistor 168 to provide a high voltage at the latch inverter output 164, the gate of the second PMOS transistor 158, and the gate of the fourth PMOS transistor 170. This biases off each of the second PMOS transistor 158 and the fourth PMOS transistor 170.

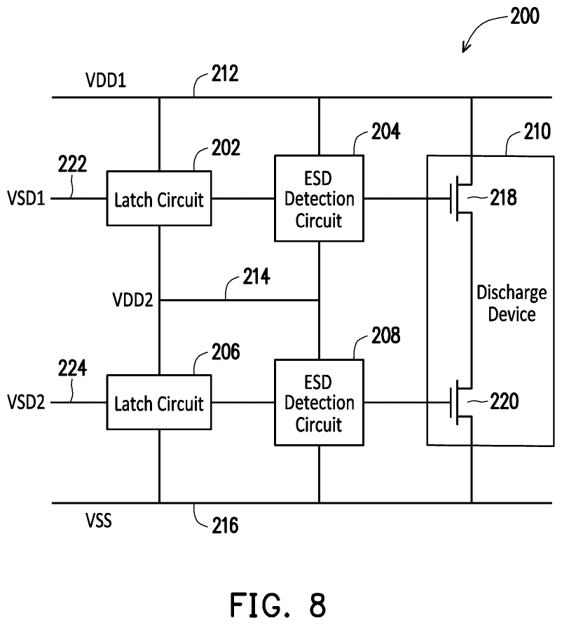

FIG. 8 is a diagram schematically illustrating an ESD protection device 200 for an overdrive circuit that includes two power voltages VDD1 and VDD2 and a reference voltage VSS, in accordance with some embodiments. The ESD protection device 200 includes a first latch circuit 202, a first ESD detection circuit 204, a second latch circuit 206, a second ESD detection circuit 208, and a discharge device 210. Also, the ESD protection device 200 includes a first net 212 that provides the first power voltage VDD1, a second net 214 that provides the second power voltage VDD2, and a third net 216 that provides the reference voltage VSS. Each of the first latch circuit 202 and the first ESD detection circuit 204 is connected to the first net 212 and the second net 214, and each of second latch circuit 206 and the second ESD detection circuit 208 is connected to the second net 214 and the third net 216. In some embodiments, the first power voltage VDD1 is at 1.5 V. In some embodiments, the second power voltage VDD2 is at 0.75 V. In some embodiments, the reference voltage VSS is at ground.

The discharge device 210 is connected to the first net 212 and the third net 216. The discharge device 210 includes a first NMOS bigFET 218 and a second NMOS bigFET 220. One end of a first drain/source path of the first NMOS bigFET 218 is connected to the first net 212 and another end of the first drain/source path is connected to a second drain/source path of the second NMOS bigFET 220. Another end of the second drain/source path is connected to the third net 216.

The first latch circuit 202 has a first input 222 that receives the first shut-down voltage VSD1 and is connected to the first ESD detection circuit 204 that is connected to a gate of the first NMOS bigFET 218. The second latch circuit 206 has a second input 224 that receives the second shut-down voltage VSD2 and is connected to the second ESD detection circuit 208 that is connected to a gate of the second NMOS bigFET 220. In some embodiments, one or more of the first latch circuit 202 and the second latch circuit 206 is like the latch circuit 26 of FIG. 1, the latch circuit 46 of FIG. 2, and/or the latch circuit 126 of FIG. 7. In some embodiments, one or more of the first ESD detection circuit 204 and the second ESD detection circuit 208 is like the ESD detection circuit 24 of FIG. 1, the ESD detection circuit 44 of FIG. 2, and/or the ESD detection circuit 124 of FIG. 7.

In operation, the first latch circuit 202 operates like the latch circuit 26 of FIG. 1, the latch circuit 46 of FIG. 2, and/or the latch circuit 126 of FIG. 7. The output of the first latch circuit 202 is latched to a high voltage that biases off the first NMOS bigFET 218 during the pre-charge stage and the ramp-up stage. Also, the second latch circuit 206 operates like the latch circuit 26 of FIG. 1, the latch circuit 46 of FIG. 2, and/or the latch circuit 126 of FIG. 7. The output of the second latch circuit 206 is latched at a high voltage that biases off the second NMOS bigFET 220 during the pre-charge stage and the ramp-up stage.

During an ESD event, the first ESD detection circuit 204 operates like the ESD detection circuit 24 of FIG. 1, the ESD detection circuit 44 of FIG. 2, and/or the ESD detection circuit 124 of FIG. 7 to bias on the first NMOS bigFET 218 for discharging the ESD current, and the second ESD detection circuit 208 operates like the ESD detection circuit 24 of FIG. 1, the ESD detection circuit 44 of FIG. 2, and/or the ESD detection circuit 124 of FIG. 7 to bias on the second NMOS bigFET 220 for discharging the ESD current. With the first NMOS bigFET 218 and the second NMOS bigFET 220 biased on, the ESD current is discharged from the first net 212 to the third net 216.

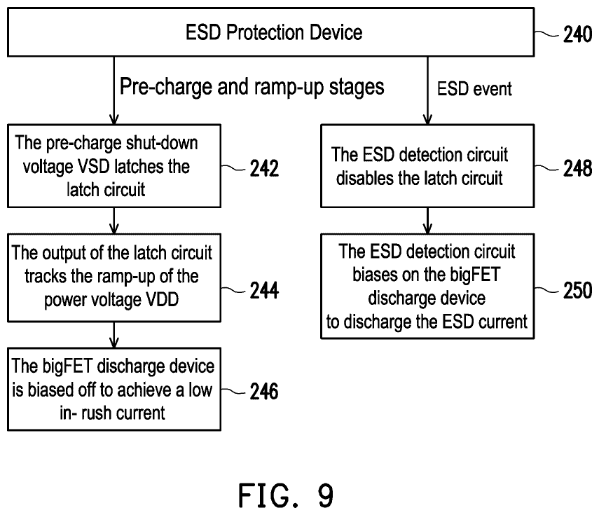

FIG. 9 is a flow-chart diagram illustrating a method of operation of an ESD protection device 240 during pre-charge and ramp-up stages and during an ESD event, in accordance with some embodiments. In some embodiments, the ESD protection device 240 is like the ESD protection device 20 of FIG. 1. In some embodiments, the ESD protection device 240 is like the ESD protection device 40 of FIG. 2. In some embodiments, the ESD protection device 240 is like the ESD protection device 120 of FIG. 7.

At step 242, the pre-charge shut-down voltage VSD latches the latch circuit and provides a high voltage at the output of the latch circuit. This biases off the bigFET discharge device and achieves a low in-rush current during the pre-charge stage.

At step 244, the output of the latch circuit tracks the ramp-up of the power voltage VDD. The bigFET discharge device is biased off by the higher voltage to achieve a low in-rush current during the ramp-up stage.

At step 246, the bigFET discharge device is biased off to achieve a low in-rush current during the pre-charge stage and the ramp-up stage.

At step 248, during an ESD event, the ESD detection circuit disables the latch circuit and, at step 250, the ESD detection circuit biases on the bigFET discharge device to discharge the ESD current.

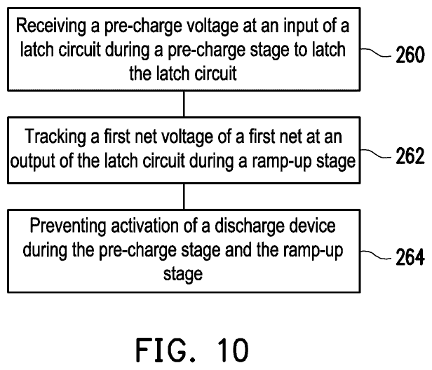

FIG. 10 is a diagram schematically illustrating a method of operating an ESD protection device, also referred to as an ESD clamp device, in accordance with some embodiments. In some embodiments, the ESD clamp device is like the ESD protection device 20 of FIG. 1. In some embodiments, the ESD clamp device is like the ESD protection device 40 of FIG. 2. In some embodiments, the ESD clamp device is like the ESD protection device 120 of FIG. 7.

At step 260, the method includes receiving a pre-charge voltage at an input of a latch circuit during a pre-charge stage to latch the latch circuit. In some embodiments, the latch circuit is like the latch circuit 26 of FIG. 1. In some embodiments, the latch circuit is like the latch circuit 46 of FIG. 2. In some embodiments, the latch circuit is like the latch circuit 126 of FIG. 7.

In some embodiments, receiving the pre-charge voltage at the input of the latch circuit during the pre-charge stage to latch the latch circuit includes receiving the pre-charge voltage at a first PMOS transistor, conducting the pre-charge voltage through the first PMOS transistor to a second PMOS transistor, and conducting the pre-charge voltage through the second PMOS transistor to the output of the latch circuit. In some embodiments, receiving the pre-charge voltage at the input of the latch circuit during the pre-charge stage to latch the latch circuit includes receiving the pre-charge voltage from the output of the latch circuit at an inverter input of an inverter, and latching the second PMOS transistor by an inverter output of the inverter.

At step 262, the method includes tracking a first net voltage of a first net at an output of the latch circuit during a ramp-up stage. In some embodiments the first net provides a power voltage VDD. In some embodiments, tracking the first net voltage at the output of the latch circuit during the ramp-up stage includes receiving the inverter output at a gate of a third PMOS transistor that is connected to the first PMOS transistor and the second PMOS transistor and to the first net, wherein the first net voltage is conducted through the third PMOS transistor and the second PMOS transistor to the output of the latch circuit.

At step 264, the method includes preventing activation of a discharge device, via the output of the latch circuit, during the pre-charge stage and the ramp-up stage. Also, in some embodiments, the method includes detecting an ESD event by an ESD detection circuit, disabling, by the ESD detection circuit, the latch circuit during the ESD event, and biasing-on, by the ESD detection circuit, the discharge device during the ESD event to discharge ESD current.

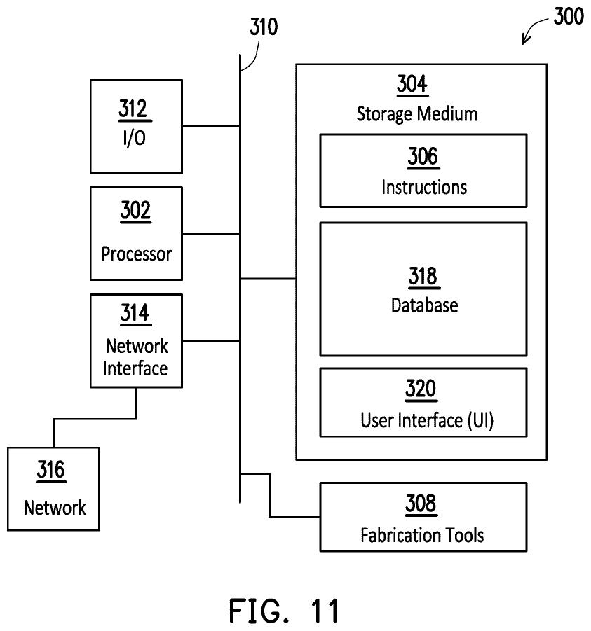

FIG. 11 is a block diagram schematically illustrating an example of a computer system 300 configured to provide the electronic devices, semiconductor devices, and methods of the current disclosure, in accordance with some embodiments. Some or all the design, layout, and manufacture of the semiconductor devices, also referred to as semiconductor circuits, can be performed by or with the aid of the computer system 300. Also, some or all the design, layout, and manufacture of the electronic devices can be performed by or with the aid of the computer system 300. In some embodiments, the computer system 300 includes an electronic design automation (EDA) system. In some embodiments, the semiconductor devices are ICs.

In some embodiments, the system 300 is a general-purpose computing device including a processor 302 and a non-transitory, computer-readable storage medium 304. The computer-readable storage medium 304 may be encoded with, e.g., store, computer program code such as executable instructions 306. Execution of the instructions 306 by the processor 302 provides (at least in part) a design tool that implements a portion or all the functions of the system 300, such as pre-layout simulations, post-layout simulations, routing, rerouting, and final layout for manufacturing. Further, fabrication tools 308 are included to further layout and physically implement the design and manufacture of the semiconductor devices. In some embodiments, execution of the instructions 306 by the processor 302 provides (at least in part) a design tool that implements a portion or all the functions of the system 300. In some embodiments, the system 300 includes a commercial router. In some embodiments, the system 300 includes an automatic place and route (APR) system.

The processor 302 is electrically coupled to the computer-readable storage medium 304 by a bus 310 and to an I/O interface 312 by the bus 310. A network interface 314 is also electrically connected to the processor 302 by the bus 310. The network interface 314 is connected to a network 316, so that the processor 302 and the computer-readable storage medium 304 can connect to external elements using the network 316. The processor 302 is configured to execute the computer program code or instructions 306 encoded in the computer-readable storage medium 304 to cause the system 300 to perform a portion or all the functions of the system 300, such as providing the semiconductor devices and methods of the current disclosure and other functions of the system 300. In some embodiments, the processor 302 is a central processing unit (CPU), a multi-processor, a distributed processing system, an application specific integrated circuit (ASIC), and/or a suitable processing unit.

In some embodiments, the computer-readable storage medium 304 is an electronic, magnetic, optical, electromagnetic, infrared, and/or semiconductor system or apparatus or device. For example, the computer-readable storage medium 304 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 304 can include a compact disk read only memory (CD-ROM), a compact disk read/write memory (CD-R/W), and/or a digital video disc (DVD).

In some embodiments, the computer-readable storage medium 304 stores computer program code or instructions 306 configured to cause the system 300 to perform a portion or all the functions of the system 300. In some embodiments, the computer-readable storage medium 304 also stores information which facilitates performing a portion or all the functions of the system 300. In some embodiments, the computer-readable storage medium 304 stores a database 318 that includes one or more of component libraries, digital circuit cell libraries, and databases.

The system 300 includes the I/O interface 312, which is coupled to external circuitry. In some embodiments, the I/O interface 312 includes a keyboard, keypad, mouse, trackball, trackpad, touchscreen, and/or cursor direction keys for communicating information and commands to the processor 302.

The network interface 314 is coupled to the processor 302 and allows the system 300 to communicate with the network 316, to which one or more other computer systems are connected. The network interface 314 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 300 can be performed in two or more systems that are like system 300.

The system 300 is configured to receive information through the I/O interface 312. The information received through the I/O interface 312 includes one or more of instructions, data, design rules, libraries of components and cells, and/or other parameters for processing by the processor 302. The information is transferred to the processor 302 by the bus 310. Also, the system 300 is configured to receive information related to a user interface (UI) through the I/O interface 312. This UI information can be stored in the computer-readable storage medium 304 as a UI 320.

In some embodiments, a portion or all the functions of the system 300 are implemented via a standalone software application for execution by a processor. In some embodiments, a portion or all the functions of the system 300 are implemented in a software application that is a part of an additional software application. In some embodiments, a portion or all the functions of the system 300 are implemented as a plug-in to a software application. In some embodiments, at least one of the functions of the system 300 is implemented as a software application that is a portion of an EDA tool. In some embodiments, a portion or all the functions of the system 300 are implemented as a software application that is used by the system 300. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 300 include fabrication tools 308 for implementing the manufacturing processes of the system 300. For example, based on the final layout, photolithographic masks may be generated, which are used to fabricate the semiconductor device by the fabrication tools 308.

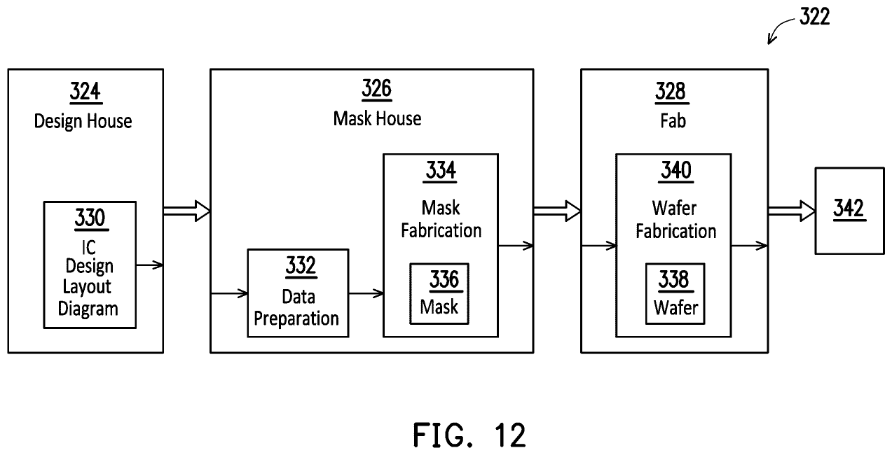

Further aspects of device fabrication are disclosed in conjunction with FIG. 12, which is a block diagram of a semiconductor device manufacturing system 322 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 322.

In FIG. 12, the semiconductor device manufacturing system 322 includes entities, such as a design house 324, a mask house 326, and a semiconductor device manufacturer/fabricator (“Fab”) 328, that interact with one another in the design, development, and manufacturing cycles and/or services related to manufacturing a semiconductor device, such as the semiconductor devices described herein. The entities in the system 322 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 324, the mask house 326, and the semiconductor device fab 328 are owned by a single larger company. In some embodiments, two or more of the design house 324, the mask house 326, and the semiconductor device fab 328 coexist in a common facility and use common resources.

The design house (or design team) 324 generates a semiconductor device design layout diagram 330. The semiconductor device design layout diagram 330 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 330 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 324 implements a design procedure to form a semiconductor device design layout diagram 330. The semiconductor device design layout diagram 330 is presented in one or more data files having information of the geometrical patterns. For example, semiconductor device design layout diagram 330 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 326 includes data preparation 332 and mask fabrication 334. The mask house 326 uses the semiconductor device design layout diagram 330 to manufacture one or more masks 336 to be used for fabricating the various layers of the semiconductor device or semiconductor structure. The mask house 326 performs mask data preparation 332, where the semiconductor device design layout diagram 330 is translated into a representative data file (RDF). The mask data preparation 332 provides the RDF to the mask fabrication 334. The mask fabrication 334 includes a mask writer that converts the RDF to an image on a substrate, such as a mask (reticle) 336 or a semiconductor wafer 338. The design layout diagram 330 is manipulated by the mask data preparation 332 to comply with characteristics of the mask writer and/or criteria of the semiconductor device fab 328. In FIG. 12, the mask data preparation 332 and the mask fabrication 334 are illustrated as separate elements. In some embodiments, the mask data preparation 332 and the mask fabrication 334 can be collectively referred to as mask data preparation.

In some embodiments, the mask data preparation 332 includes an optical proximity correction (OPC) which uses lithography enhancement techniques to compensate for image errors, such as those that can arise from diffraction, interference, other process effects and the like. The OPC adjusts the semiconductor device design layout diagram 330. In some embodiments, the mask data preparation 332 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 332 includes a mask rule checker (MRC) that checks the semiconductor device design layout diagram 330 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 330 to compensate for limitations during the mask fabrication 334, which may undo part of the modifications performed by OPC to meet mask creation rules.

In some embodiments, the mask data preparation 332 includes lithography process checking (LPC) that simulates processing that will be implemented by the semiconductor device fab 328. LPC simulates this processing based on the semiconductor device design layout diagram 330 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 330.

The above description of mask data preparation 332 has been simplified for the purposes of clarity. In some embodiments, data preparation 332 includes additional features such as a logic operation (LOP) to modify the semiconductor device design layout diagram 330 according to manufacturing rules. Additionally, the processes applied to the semiconductor device design layout diagram 330 during data preparation 332 may be executed in a variety of different orders.

After the mask data preparation 332 and during the mask fabrication 334, a mask 336 or a group of masks 336 are fabricated based on the modified semiconductor device design layout diagram 330. In some embodiments, the mask fabrication 334 includes performing one or more lithographic exposures based on the semiconductor device design layout diagram 330. In some embodiments, an electron-beam (e-beam) or a mechanism of multiple e-beams is used to form a pattern on a mask (photomask or reticle) 336 based on the modified semiconductor device design layout diagram 330. The mask 336 can be formed in various technologies. In some embodiments, the mask 336 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 336 includes a transparent substrate (e.g., fused quartz) and an opaque material (e.g., chromium) coated in the opaque regions of the binary mask. In another example, the mask 336 is formed using a phase shift technology. In a phase shift mask (PSM) version of the mask 336, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 334 is used in a variety of processes. For example, such a mask(s) is used in an ion implantation process to form various doped regions in the semiconductor wafer 338, in an etching process to form various etching regions in the semiconductor wafer 338, and/or in other suitable processes.

The semiconductor device fab 328 includes wafer fabrication 340. The semiconductor device fab 328 is a semiconductor device fabrication business that includes one or more manufacturing facilities for the fabrication of a variety of different semiconductor device products. In some embodiments, the semiconductor device fab 328 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 328 uses the mask(s) 336 fabricated by the mask house 326 to fabricate the semiconductor structures or semiconductor devices 342 of the current disclosure. Thus, the semiconductor device fab 328 at least indirectly uses the semiconductor device design layout diagram 330 to fabricate the semiconductor structures or semiconductor devices 342 of the current disclosure. Also, the semiconductor wafer 338 includes a silicon substrate or other proper substrate having material layers formed thereon, and the semiconductor wafer 338 further includes one or more of various doped regions, dielectric features, multilevel interconnects, and the like (formed at subsequent manufacturing steps). In some embodiments, the semiconductor wafer 338 is fabricated by the semiconductor device fab 328 using the mask(s) 336 to form the semiconductor structures or semiconductor devices 342 of the current disclosure. In some embodiments, the semiconductor device fabrication includes performing one or more lithographic exposures based at least indirectly on the semiconductor device design layout diagram 330.

Thus, disclosed embodiments provide a device including a discharge device, an ESD detection circuit, and a latch circuit. The discharge device is connected to a first net, such as a power voltage net VDD, and a second net, such as a reference voltage net VSS, and configured to discharge ESD current during an ESD event. The ESD detection circuit is connected to the discharge device and configured to detect the ESD event and activate the discharge device to discharge ESD current during the ESD event. The latch circuit includes an input configured to receive a pre-charge voltage, such as a shut-down voltage VSD, to latch the latch circuit during a pre-charge stage and track the voltage on the first net at an output of the latch circuit during a ramp-up stage. The output is coupled to the discharge device to prevent activation of the discharge device during the pre-charge stage and the ramp-up stage, which provides a low in-rush current during the pre-charge stage and the ramp-up stage.

Advantages of the ESD protection device and method of operating the device include preventing activation of the discharge device during the pre-charge stage to achieve low in-rush current, tracking the output of the latch circuit to the power voltage VDD during the ramp-up stage to prevent activation of the discharge device and achieve low in-rush current during the ramp-up stage, and disabling the latch circuit and activating the discharge device, by an ESD detection circuit, to discharge ESD currents through the discharge device during an ESD event.

In accordance with some embodiments, a device includes a discharge device, an ESD detection circuit, and a latch circuit. The discharge device is connected to a first net and a second net and configured to discharge ESD current during an ESD event. The ESD detection circuit is connected to the discharge device and configured to detect the ESD event and activate the discharge device to discharge the ESD current during the ESD event. The latch circuit including an input and an output, the input configured to receive a pre-charge voltage to latch the latch circuit during a pre-charge stage and track a first net voltage on the first net at the output during a ramp-up stage. The output coupled to the discharge device to prevent activation of the discharge device during the pre-charge stage and the ramp-up stage.

In accordance with further embodiments, a device includes a discharge device, an ESD detection circuit, and a latch circuit. The discharge device is connected to a first net and a second net and configured to discharge ESD current during an ESD event. The ESD detection circuit is connected to the discharge device and configured to detect the ESD event and activate the discharge device to discharge the ESD current during the ESD event. The latch circuit includes an input and an output, the input configured to receive a pre-charge voltage to latch the latch circuit during a pre-charge stage and track a first net voltage of the first net at the output during a ramp-up stage. The output is coupled to the discharge device to prevent activation of the discharge device during the pre-charge stage and the ramp-up stage. The latch circuit includes a first PMOS transistor, a second PMOS transistor, and a latch inverter. The first PMOS transistor has a first gate connected to the first net and a first drain/source path connected to the input of the latch circuit. The second PMOS transistor has a second gate and a second drain/source path connected to the first drain/source path and to the output of the latch circuit. The latch inverter has a latch inverter input and a latch inverter output, the latch inverter input is connected to the output of the latch circuit, and the latch inverter output is connected to the second gate of the second PMOS transistor.

In accordance with still further disclosed aspects, a method of operating an ESD clamp device includes: receiving a pre-charge voltage at an input of a latch circuit during a pre-charge stage to latch the latch circuit; tracking a first net voltage of a first net at an output of the latch circuit during a ramp-up stage; and preventing activation of a discharge device during the pre-charge stage and the ramp-up stage.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a discharge device connected to a first net and a second net and configured to discharge electro-static discharge (ESD) current during an ESD event;
an ESD detection circuit connected to the discharge device and configured to detect the ESD event and activate the discharge device to discharge the ESD current during the ESD event; and
a latch circuit including an input and an output, the input is configured to receive a pre-charge voltage to latch the latch circuit during a pre-charge stage and track a first net voltage on the first net at the output during a ramp-up stage, the output is coupled to the discharge device to prevent activation of the discharge device during the pre-charge stage and the ramp-up stage.

2. The device of claim 1, wherein the discharge device includes an NMOS bigFET.

3. The device of claim 1, wherein the ESD detection circuit includes a resistor-capacitor (RC) network and an inverter having an inverter input and an inverter output, the RC network is connected to the inverter input and the discharge device is connected to the inverter output.

4. The device of claim 1, wherein the output of the latch circuit is connected to the RC network and the inverter input.

5. The device of claim 1, wherein the output of the latch circuit is connected to the discharge device.

6. The device of claim 1, wherein the latch circuit includes a first PMOS transistor having a first drain/source path connected to the input of the latch circuit and to a second drain/source path of a second PMOS transistor that is connected to the output of the latch circuit.

7. The device of claim 6, wherein a first gate of the first PMOS transistor is connected to the first net.

8. The device of claim 6, comprising a latch inverter having a latch inverter input and a latch inverter output, wherein the output of the latch circuit is connected to the latch inverter input and a second gate of the second PMOS transistor is connected to the latch inverter output.

9. The device of claim 8, wherein the latch inverter includes a third PMOS transistor and a first NMOS transistor, the third PMOS transistor having a third drain/source path connected to the first net and to a fourth drain/source path of the first NMOS transistor that is connected to the second net.

10. The device of claim 9, comprising a fourth PMOS transistor connected to the first drain/source path and the second drain/source path and to the first net, wherein a gate of the fourth PMOS transistor is connected to the latch inverter output.

11. A device, comprising:
a discharge device connected to a first net and a second net and configured to discharge electro-static discharge (ESD) current during an ESD event;
an ESD detection circuit connected to the discharge device and configured to detect the ESD event and activate the discharge device to discharge the ESD current during the ESD event; and
a latch circuit including an input and an output, the input is configured to receive a pre-charge voltage to latch the latch circuit during a pre-charge stage and track a first net voltage of the first net at the output during a ramp-up stage, the output coupled to the discharge device to prevent activation of the discharge device during the pre-charge stage and the ramp-up stage,
wherein the latch circuit includes:
a first PMOS transistor having a first gate connected to the first net and a first drain/source path connected to the input of the latch circuit;
a second PMOS transistor having a second gate and having a second drain/source path connected to the first drain/source path and to the output of the latch circuit; and
a latch inverter having a latch inverter input and a latch inverter output, the latch inverter input connected to the output of the latch circuit, and the latch inverter output connected to the second gate of the second PMOS transistor.

12. The device of claim 11, wherein the latch inverter includes a third PMOS transistor and a first NMOS transistor, the third PMOS transistor having a third drain/source path connected to the first net and to a fourth drain/source path of the first NMOS transistor that is connected to the second net.

13. The device of claim 12, comprising a fourth PMOS transistor connected to the first drain/source path and the second drain/source path and to the first net, wherein a gate of the fourth PMOS transistor is connected to the latch inverter output.

14. The device of claim 11, wherein the ESD detection circuit includes a resistor-capacitor (RC) network and an inverter having an inverter input and an inverter output, the RC network is connected to the inverter input and the discharge device is connected to the inverter output, wherein the output of the latch circuit is connected to the RC network and the inverter input.

15. The device of claim 11, wherein the output of the latch circuit is connected to the discharge device.

16. A method of operating an electro-static discharge (ESD) clamp device, the method includes:
receiving a pre-charge voltage at an input of a latch circuit during a pre-charge stage to latch the latch circuit;
tracking a first net voltage of a first net at an output of the latch circuit during a ramp-up stage; and
preventing activation of a discharge device during the pre-charge stage and the ramp-up stage.

17. The method of claim 16, comprising:
detecting an ESD event by an ESD detection circuit;
disabling, by the ESD detection circuit, the latch circuit during the ESD event; and
biasing-on, by the ESD detection circuit, the discharge device during the ESD event to discharge ESD current.

18. The method of claim 16, wherein receiving the pre-charge voltage at the input of the latch circuit during the pre-charge stage to latch the latch circuit includes:
receiving the pre-charge voltage at a first PMOS transistor;
conducting the pre-charge voltage through the first PMOS transistor to a second PMOS transistor; and
conducting the pre-charge voltage through the second PMOS transistor to the output of the latch circuit.

19. The method of claim 18, wherein receiving the pre-charge voltage at the input of the latch circuit during the pre-charge stage to latch the latch circuit includes:
receiving the pre-charge voltage from the output of the latch circuit at an inverter input of an inverter; and
latching the second PMOS transistor by an inverter output of the inverter.

20. The method of claim 19, wherein tracking the first net voltage at the output of the latch circuit during the ramp-up stage includes:
receiving the inverter output at a gate of a third PMOS transistor that is connected to the first PMOS transistor and the second PMOS transistor and to the first net, wherein the first net voltage is conducted through the third PMOS transistor and the second PMOS transistor to the output of the latch circuit.
